(19) United States
(12) Patent Application Publication
(10) Pub. No.: US 2015/0078863 A1
(43) Pub. Date: Mar. 19, 2015

(54) CONVEYOR

(71) Applicant: TOKYO ELECTRON LIMITED, Tokyo (JP)

(72) Inventor: Tsutomu HIROKI, Nirasaki City (JP)

(21) Appl. No.: 14/550,261

(22) Filed: Nov. 21, 2014

Related U.S. Application Data
(63) Continuation of application No. PCT/JP2013/063615, filed on May 9, 2013.

(30) Foreign Application Priority Data
May 22, 2012 (JP) 2012-116851

(51) Int. Cl. H01L 21/677; B25J 11/00

(52) U.S. Cl. CPC H01L 21/67703; B25J 11/0095; H01L 21/67739
USPC 414/217

(57) ABSTRACT

A transfer device configured by connecting a plurality of housing-shaped transfer units in series includes: a pair of coil arrays including a plurality of coils arranged in the transfer units along an arrangement direction of the transfer units; a transfer base disposed between the coil arrays; and a plurality of fitting parts installed in one to one correspondence with the coils, the fitting parts being interposed between the coils and inner wall surfaces of the transfer units, wherein the transfer base has magnets facing the coil arrays, a plurality of through holes are formed in one to one correspondence with the coils in each of the transfer units, each of the fitting parts has a bar-shaped protrusion configured to be inserted into a corresponding one of the through holes, and a sealing member is interposed between the protrusion and the corresponding one of the through holes.

### CROSS-REFERENCE TO RELATED APPLICATIONS

This application is a Continuation Application of PCT International Application No. PCT/JP2013/063615, filed on May 9, 2013, which claimed the benefit of Japanese Patent Application No. 2012-116851, filed on May 22, 2012, the entire content of each of which is hereby incorporated by reference.

### TECHNICAL FIELD

The present disclosure relates to a transfer device configured by combining a plurality of transfer units and having a transfer base movable by a linear motor mechanism.

### BACKGROUND

In a substrate processing system for processing substrates, for example, semiconductor device wafers (hereinafter, simply referred to as “wafers”), wafer processing efficiency can be improved by providing a plurality of process modules, each of which is a substrate processing apparatus that processes substrates one by one.

The substrate processing system further includes a load lock module, which is a loading/unloading device for loading and unloading wafers to and from the substrate processing system, and a transfer module that is a transfer device connected to the load lock module. The plurality of process modules are connected to the transfer module. The transfer module has a transfer base for transferring wafers, and the transfer base is moved within the transfer module to transfer the wafers between the load lock module and the respective process modules.

In general, in order to efficiently arrange the plurality of process modules, the transfer module consists of a chamber elongated in one direction, and the transfer base is moved within the transfer module in the elongated direction.

Conventionally, a ball screw mechanism has been used as a moving mechanism of the transfer base. For example, the ball screw mechanism has a feed screw 101 disposed within a transfer module 100 along an elongated direction of the transfer module 100, and a feed screw hole 103 provided in a transfer base 102 and screw-coupled with the feed screw 101, as illustrated in FIG. 10. As the feed screw 101 is rotated about its axis, the feed screw hole 103 converts the rotational force of the feed screw 101 to the moving force of the transfer base 102, so that the transfer base 102 is moved along the feed screw 101. The Y, X, and Z directions in FIG. 10 indicate the moving direction of the transfer base 102, the direction perpendicular to the moving direction of the transfer base 102 in a wafer transfer plane, and the height direction of the transfer module 100, respectively.

Wafers that have an enlarged diameter require enlargement of the process module and further the transfer module. If the transfer module is enlarged, it is necessary to make the feed screw 101 longer in order to increase a moving amount of the transfer base.

The feed screw 101 is formed in the shape of a round bar, and thus the feed screw 101 is easily bent. Accordingly, if the feed screw 101 is made longer, there is a problem in that it is difficult for the transfer base 102 to be accurately moved, because the feed screw 101 is bent due to the weight of the transfer base.

Therefore, a magnetic driving mechanism has been introduced to move a transfer base. For example, the magnetic driving mechanism has a rail 111 disposed within a transfer module 110 along the elongated direction of the transfer module 110, an arm 112 movable along the rail 111, and a driver (not shown) movable outside the transfer module 110 along the rail 111, as illustrated in FIG. 11. In the transfer module 110, since a magnetic head (not shown) of the arm 112 is magnetically coupled with the driver, the magnetic head and further the arm 112 are moved along with the movement of the driver. The shape of the rail 111 is not specifically limited, because the rail 111 needs only to guide the arm 112. Even when the rail 111 is made longer, for example, the rail 111 can be suppressed from being bent and the arm 112 can be moved accurately, by increasing the height of the rail 111 to increase the second moment of area of the rail 111. The Y and X directions in FIG. 12 indicate the moving direction of the arm 112 and the direction perpendicular to the moving direction of the arm 112 in a wafer transfer plane, respectively.

However, the transfer module 110 of FIG. 11 has a problem in that metal powder or the like is generated due to the contact between the rail 111 and the arm 112, which contaminates a wafer. In addition, although it is necessary to flexibly control the number of wafers to be processed due to the large fluctuation in demand for semiconductor devices, the transfer module 110 of FIG. 11 has a problem in that, since the rail 111 is formed in the shape of a single bar, it is difficult to extend the rail 111 and thus it is impossible to flexibly control the number of wafers to be processed by increasing the number of process modules.

In order to cope with the aforementioned problems, it has been studied, recently, to use a linear motor mechanism for moving the transfer base.

FIG. 12 is a plane view illustrating a schematic configuration of a conventional substrate processing system using a linear motor mechanism. In addition, for illustrative purposes, FIG. 12 shows a state where lids of transfer units 121 to be described later are removed. The Y and X directions in FIG. 12 indicate the moving direction of a transfer base 126 described later and the direction perpendicular to the moving direction of the transfer base 126 in a wafer transfer plane, respectively.

In FIG. 12, a substrate processing system 120 includes a transfer module 122 configured by serially connecting the transfer units 121, each of the transfer units 121 consisting of a chamber in the shape of a housing, a plurality of process modules 123 connected to the respective transfer units 121, and two load lock modules 124 connected to one end of the transfer module 122.

In addition, the substrate processing system 120 further includes a pair of coil arrays 125 arranged within the transfer module 122 along the elongated direction of the transfer module 122, and the rectangular parallelepiped transfer base 126 interposed between the coil arrays 125.

Magnets 127 are disposed at both sides of the transfer base 126 to face the coil arrays 125, respectively, so that the transfer base 126 is moved along the coil arrays 125 by an electromagnetic force generated when respective coils 128 of the coil arrays 125 are powered on . Since the transfer base 126 is attracted by the electromagnetic force toward the respective coil arrays 125 with the transfer base 126 interposed therebetween, the transfer base 126 is positioned in the center between both the coil arrays 125 and thus is not in contact with any one of the coil arrays 125.

The transfer module 122 may be elongated by installing additional transfer units 121. In such a case, each of the coil arrays 125 may be easily extended by arranging additional coils 128 in the additional transfer units 121.

In each of the transfer units 121 of FIG. 12, since it is necessary to connect power supply wires 132 to the respective coils 128 from the outside, as illustrated in FIG. 13, through holes 129 need to be machined and bored through a wall surface of each transfer unit 121. The inside of the transfer unit 121 is in communication with the inside of the process module 123, and thus the inside of the transfer unit 121 is depressurized. Thus, it is necessary to block the through holes 129 with the coils 128 and also to seal gaps between the coils 128 and the inner wall surface of the transfer unit 121. Accordingly, seal grooves 130 for inserting sealing members, such as O-rings, need to be formed in the inner wall surface of the transfer unit 121. However, the seal grooves 130 cannot be formed for the coil 128 disposed in the vicinity of an end portion 121a of the transfer unit 121, because a ceiling portion 121b of the transfer unit 121 interferes with a machining tool 131 so that the machining tool 131 does not reach a desirable machining position. In addition, for the same reason, screw holes 133 for coil installation cannot be formed. As a result, since the coils 128 cannot be disposed in the vicinity of the end portion 121a of the transfer unit 121, the plurality of coils 128 cannot be uniformly disposed in each of the coil arrays 125, and thus the electromagnetic force cannot be uniformly exerted on the transfer base 126. Therefore, there is a problem in that the transfer base 126 cannot be smoothly moved. The Y and Z directions in FIG. 13 indicate the arrangement direction the plurality of coils 128 and the height direction of the transfer units 121, respectively.

### SUMMARY

The present disclosure provides some embodiments of a transfer device capable of realizing smooth movement of a transfer base by securing a degree of freedom in coil arrangement.

According to one embodiment of the present disclosure, there is provided a transfer device configured by connecting a plurality of housing-shaped transfer units in series, the transfer device including: a pair of coil arrays including a plurality of coils arranged in the transfer units along an arrangement direction of the plurality of transfer units; a transfer base disposed between the pair of coil arrays and configured to move in the transfer unit along the arrangement direction to transfer a substrate; and a plurality of fitting parts installed in one to one correspondence with the coils, each of the fitting parts being interposed between a corresponding one of the coils and an inner wall surface of one of the transfer units so that each of the coils is installed on a corresponding one of the fitting parts. An inside of each of the transfer units is depressurized below atmospheric pressure. The transfer base has a plurality of magnets facing each of the pair of coil arrays. A plurality of through holes is formed in one to one correspondence with the coils in each of the transfer units, the through holes penetrating from inside of the transfer units to outside of the transfer units. Each of the fitting parts has a bar-shaped protrusion configured to be inserted into a corresponding one of the through holes. A sealing member is interposed between the protrusion and the corresponding one of the through holes.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plane view illustrating a schematic configuration of a substrate processing system having a transfer device according to an embodiment of the present disclosure.

FIG. 2 is a perspective view illustrating a positional relationship between coil arrays, power supply wires and a slide box inside a transfer unit in FIG. 1.

FIG. 3 is a sectional view illustrating the positional relationship between the coil arrays, the power supply wires and the slide box inside the transfer unit in FIG. 1.

FIG. 4 is a perspective view illustrating a schematic configuration of an adaptor for coil installation.

FIG. 5 is a sectional view illustrating an installation state of the adaptor to the transfer unit.

FIG. 6 is a sectional view illustrating a state of machining a through hole in the transfer unit.

FIGS. 7A and 7B are views illustrating a method for resolving misalignment in rotational directions of the respective coils in the coil array.

FIG. 8 is a perspective view illustrating a schematic configuration of a first modification of the adaptor of FIG. 4.

FIG. 9 is a perspective view illustrating a schematic configuration of a second modification of the adaptor of FIG. 4.

FIG. 10 is a transparent perspective view illustrating a schematic configuration of a conventional transfer module using a ball screw mechanism.

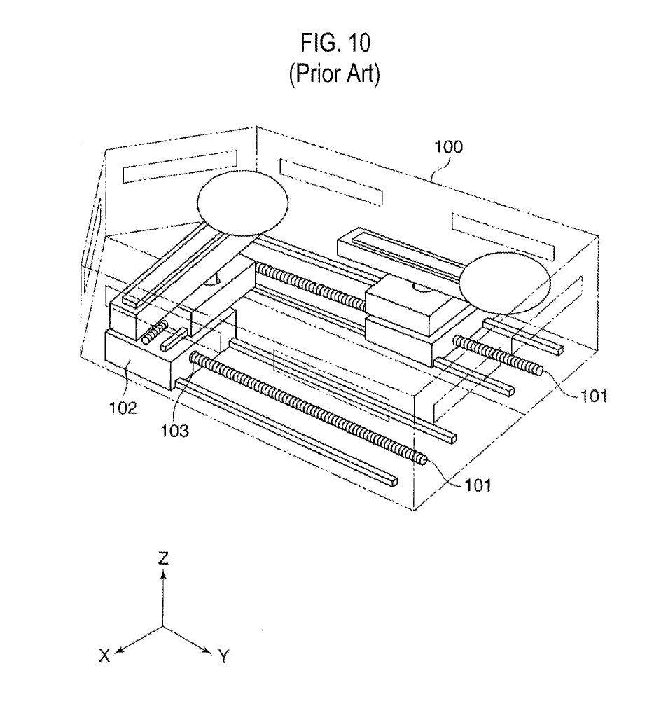

FIG. 11 is a plane view illustrating a schematic configuration of a conventional transfer module using a magnetic driving mechanism.

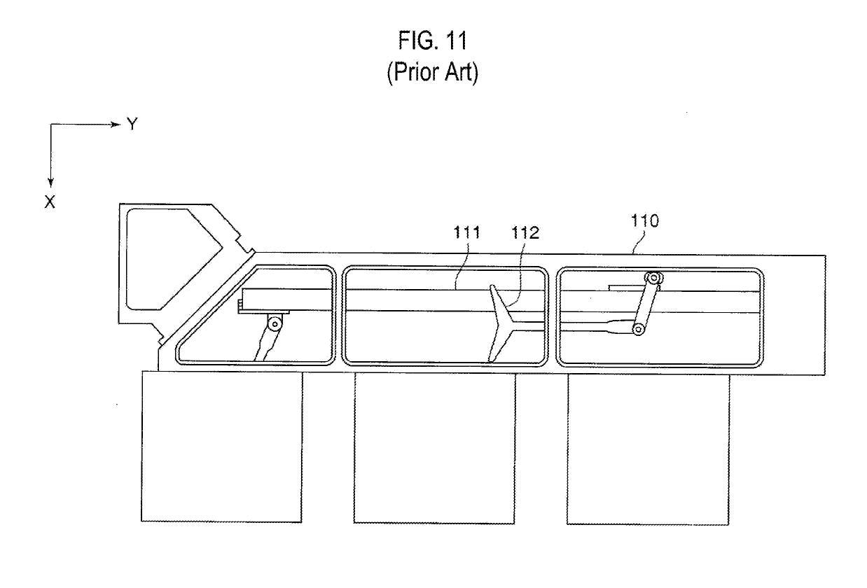

FIG. 12 is a plane view illustrating a schematic configuration of a conventional substrate processing system using a linear motor mechanism.

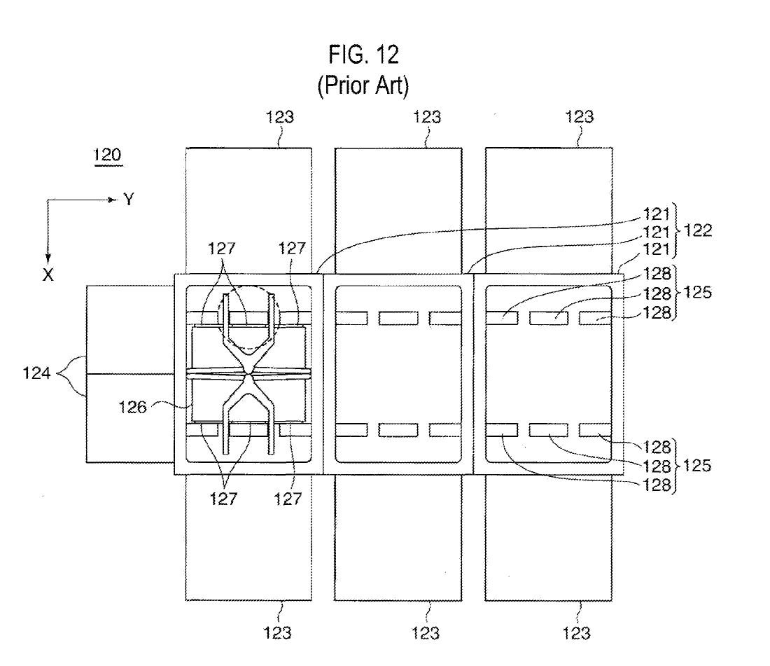

FIG. 13 is a sectional view illustrating a state of machining seal grooves or screw holes for coil installation in an inner wall surface of a transfer unit of FIG. 12.

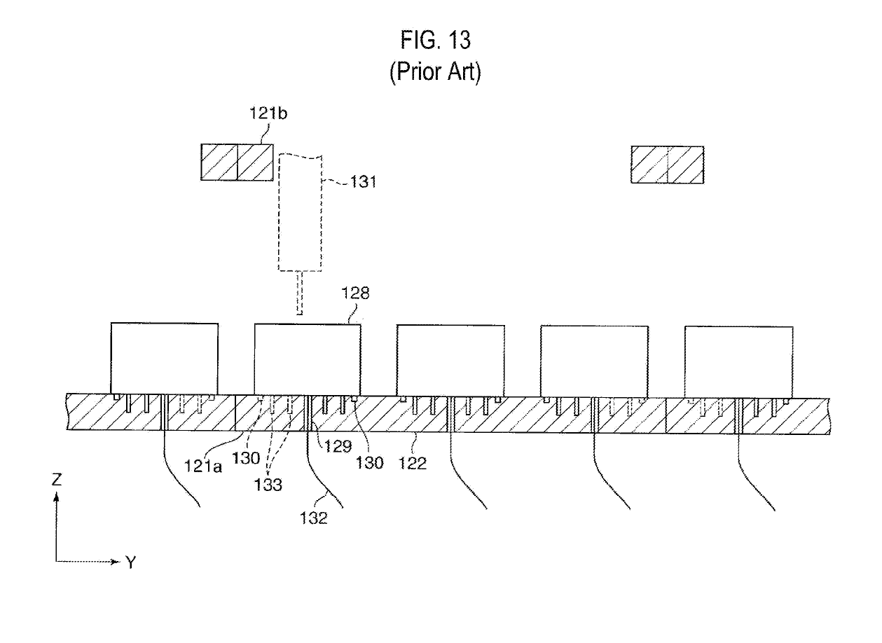

### DETAILED DESCRIPTION

Hereinafter, embodiments of the present disclosure will be described with reference to the drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

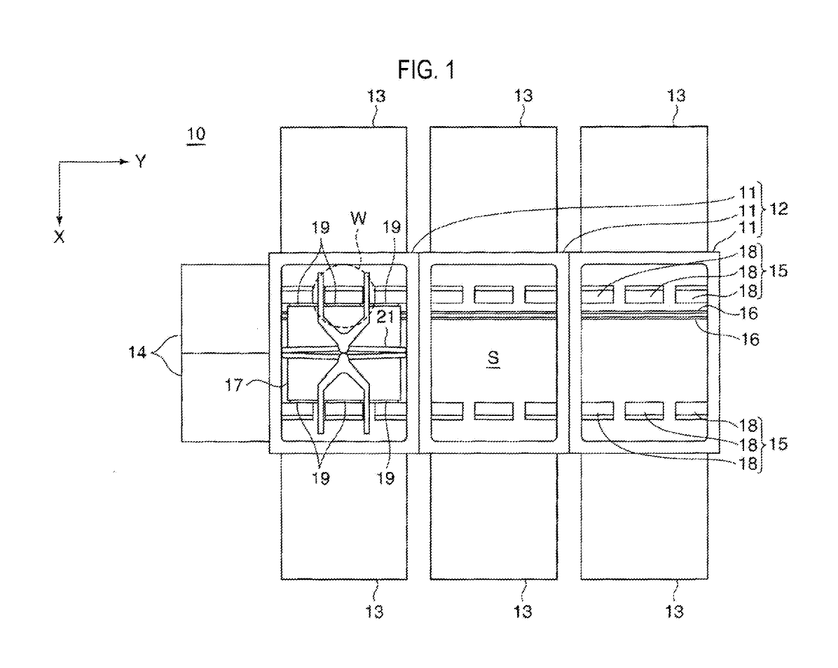

FIG. 1 is a plane view illustrating a schematic configuration of a substrate processing system having a transfer device according to an embodiment of the present disclosure. For illustrative purposes, FIG. 1 illustrates a state where lids of transfer units 11 described later are removed. In FIGS. 1 to 9, Y, X and Z directions indicate a moving direction of a slide box 17 described later, a direction perpendicular to the moving direction of the slide box 17 in a wafer transfer plane, and a height direction of a transfer module 12 described later, respectively.

In FIG. 1, a substrate processing system 10 includes the transfer module (transfer device) 12 configured by serially connecting the transfer units 11. Each of the transfer units 11 consists of a chamber in the shape of a housing, a plurality of process modules 13 connected to the respective transfer units 11, and two load lock modules 14 connected to one end of the transfer module 12.

For each of the transfer units 11, two of the process modules 13 are arranged to face each other with the corresponding transfer unit 11 interposed therebetween. The inside of each process module 13 is depressurized, and a plasma process, for example, a dry etching process or a film forming process, is performed on a wafer W accommodated in the process module 13.

In the transfer module 12, the inside of the transfer units 11 communicate with each other to define a transfer space S. The transfer space S is depressurized below atmospheric pressure by an exhaust device or pressure valves (both not shown), with which the transfer module 12 is provided. Specifically, a pressure of the transfer space S is set to be almost the same as the internal pressure of each process module 13.

The transfer module 12 has a pair of coil arrays 15 arranged along the arrangement direction of the transfer units 11, two power supply wires 16 arranged in parallel with the coil arrays 15, and the rectangular parallelepiped slide box (transfer base) 17 disposed within the transfer space S.

The coil arrays 15 consist of a plurality of rectangular coils 18, which are arranged in two parallel rows on the inside bottom portion of each transfer unit 11. Each of the coils 18 is supplied with electric power from the outside of the transfer module 12, and switches magnetic poles according to the supplied electric power to generate an electromagnetic force. Each of the power supply wires 16 is formed in the shape of a pipe arranged on the inside bottom portion of each transfer unit 11, and is supplied with electric power from the outside of the transfer module 12.

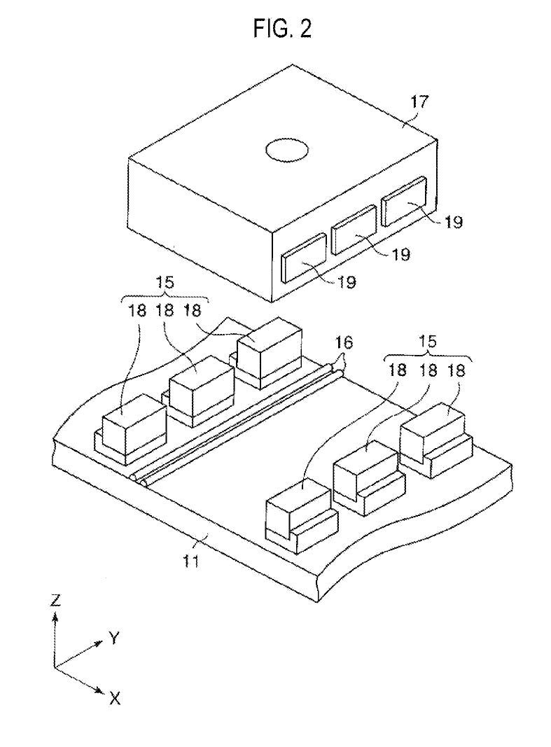

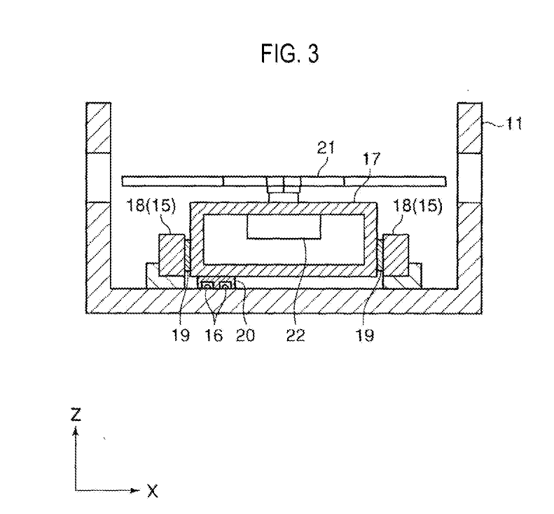

FIG. 2 is a perspective view illustrating a positional relationship between the coil arrays, the power supply wires and the slide box inside the transfer unit in FIG. 1, and FIG. 3 is a sectional view illustrating the positional relationship between the coil arrays, the power supply wires and the slide box inside the transfer unit in FIG. 1. For simplification of description, in FIG. 2, a transfer arm 21 described later and sidewalls of the transfer unit 11 are omitted, and the slide box 17 is spaced apart from the bottom portion of the transfer unit 11.

In FIGS. 2 and 3, the slide box 17 is interposed between the pair of coil arrays 15, and a plurality of permanent magnets 19 are arranged on both sides of the slide box 17 to face the coil arrays 15, respectively. The coil arrays 15 and the permanent magnets 19 constitute a linear motor mechanism, and the electromagnetic force generated by the coils 18 electromagnetically drives and moves the slide box 17 along the coil arrays 15. Since the slide box 17 is interposed between the pair of coil arrays 15, the slide box 17 is pulled toward the respective coil arrays 15 and positioned in the center between the coil arrays 15 without being in contact with any one of the coil arrays 15. Accordingly, it is possible to suppress generation of particles such as metal powder caused by the contact, and thus the wafer W transferred by the slide box 17 can be prevented from being contaminated by particles. The slide box 17 may be supported by a guide (not shown) or supported in a floating manner by magnet arrays (not shown) disposed on the inner sidewalls or the like of each transfer unit 11.

The slide box 17 has the rotatable and extendable transfer arm 21 on the top thereof, an electric unit 22 in an inside thereof for driving the transfer arm 21 and also communicating with a control unit (not shown) of the substrate processing system 10, and a power receiving transformer 20 on the bottom thereof. The power supply wires 16 supply electric power to the electric unit 22 in a non-contact manner through the power receiving transformer 20, and the electric unit 22 controls the driving of the transfer arm 21 based on a control signal received from the control unit.

The transfer module 12 performs loading and unloading of the wafer W to and from the process modules 13 by combining the movement of the slide box 17 and the rotation and extension of the transfer arm 21.

Returning to FIG. 1, the load lock modules 14 perform loading and unloading of the wafer W between the transfer module 12 and the outside of the substrate processing system 10. Each of the load lock modules 14 is configured such that the inside thereof can be depressurized. When the wafer W is loaded into the transfer module 12 from the outside of the substrate processing system 10, the load lock module 14 receives the wafer W from a container of the wafer W, for example a FOUP, the inside of the load lock module 14 is depressurized to the same pressure as that of the transfer space S, and then the load lock module 14 delivers the wafer W to the transfer arm 21 of the slide box 17. When the wafer W is unloaded from the transfer module 12 to the outside of the substrate processing system 10, the load lock module 14 receives the wafer W from the transfer arm 21, the internal pressure of the load lock module 14 is increased to atmospheric pressure, and then the load lock module 14 delivers the wafer W to the FOUP.

In the substrate processing system 10, the transfer module 12 may be elongated by installing an additional transfer unit 11. Specifically, the additional transfer unit 11 is connected to an end portion of the transfer module 12 opposite to the end portion where the load lock modules 14 are connected, and the inside of the additional transfer unit 11 communicates with the transfer space S, thereby elongating the transfer module 12. Like the other transfer units 11, a plurality of rectangular coils 18 are arranged in two parallel rows and two power supply wires 16 are disposed on the inside bottom portion of the additional transfer unit 11. Thus, when the additional transfer unit 11 is connected to the transfer module 12, the plurality of coils 18 of the additional transfer unit 11 elongate the pair of coil arrays 15 of the transfer module 12, and the power supply wires 16 of the additional transfer unit 11 elongate the respective power supply wires 16 of the transfer module 12.

Therefore, in the substrate processing system 10, the transfer module 12 can be easily elongated, and accordingly, process modules 13 connected to the transfer unit 11 can be additionally installed. On the contrary, by removing one or more of the transfer units 11 from the transfer module 12, the transfer module 12 can be easily shortened, and accordingly, the process modules 13 can be reduced in number. That is, the number of wafers W to be processed can be easily increased and decreased in the substrate processing system 10.

In transfer modules using the conventional linear motor mechanism, when the coils are arranged on the inside bottom portion of the transfer unit, it is necessary to form seal grooves for inserting sealing members in the inner wall surface of the transfer unit in order to seal gaps between the coils and the inner wall surface of the transfer unit.

In the transfer module 12 as the transfer device according to the present embodiment, in order not to form the seal grooves in the inner wall surfaces of the transfer units 11, adaptors (fitting parts) 23 are interposed between the coils 18 and the inner wall surfaces of the transfer units 11. The adaptors 23 are installed in one to one correspondence with the coils 18, and each of the coils 18 is installed on a corresponding one of the adaptors 23.

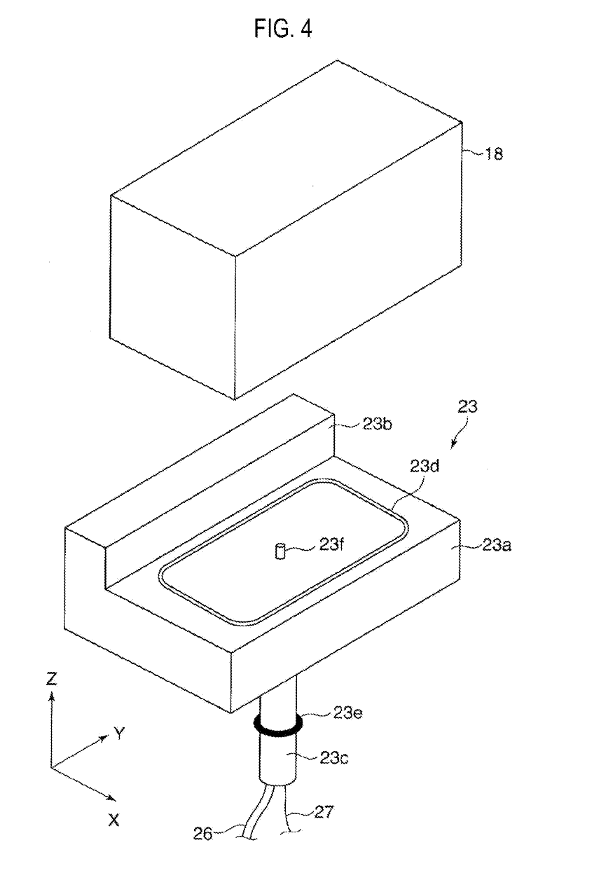

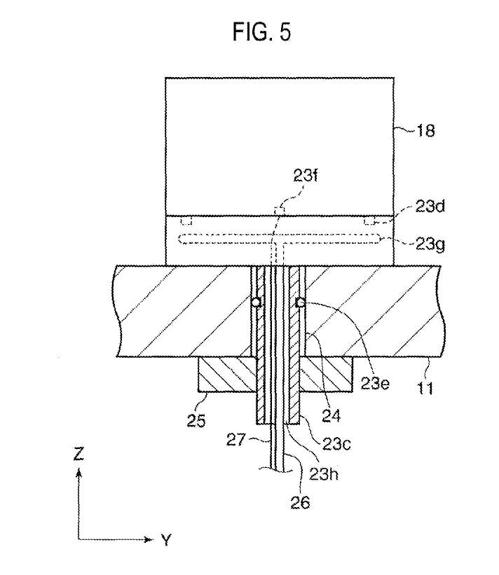

FIG. 4 is a perspective view illustrating a schematic configuration of the adaptor for coil installation, and FIG. 5 is a sectional view illustrating an installation state of the adaptor to the transfer unit. For simplification of description, the coil 18 is spaced apart from the adaptor 23 in FIG. 4.

In FIGS. 4 and 5, the adaptor 23 has a base portion 23a in the shape of a rectangular flat plate, a wall-shaped stopper 23b protruding upward in the drawings from the base portion 23a, and a bar-shaped shaft (protrusion) 23c protruding downward in the drawings from about the center of the base portion 23a.

The upper surface of the base portion 23a forms a contact surface with the coil 18 when the coil 18 is installed on the adaptor 23. A seal groove 23d for inserting a sealing member, for example, an O-ring (not shown), to seal the gap between the coil 18 and the contact surface is formed in the contact surface, and an electric contact 23f as a protrusion for supplying electric power to the coil 18 is also installed on the contact surface. The stopper 23b is brought into contact with a lateral surface of the coil 18 when the coil 18 is installed on the adaptor 23, which prevents positional misalignment of the coil 18 with respect to the adaptor 23. A lateral side of the shaft 23c is male-threaded, and an O-ring (sealing member) 23e is disposed to surround the shaft 23c approximately in the center of the shaft 23c in its length direction. Specifically, the O-ring 23e is disposed on the shaft 23c by inserting the O-ring 23e into an O-ring groove formed along the circumferential direction of the shaft 23c.

Through holes 24 for coil installation are formed in one to one correspondence with the coils 18 in the bottom portion of the transfer unit 11. When the coils 18 are arranged on the inside bottom portion of the transfer unit 11, the coils 18 are first installed on the corresponding adaptor 23, and then the shaft 23c of the adaptor 23 is inserted into the corresponding through hole 24 from the inside bottom portion of the transfer unit 11. Then, a nut 25 is screw-coupled to a portion of the shaft 23c protruding from the through hole 24 to the outside of the transfer unit 11, thereby tightly fixing the adaptor 23 to the transfer unit 11. Here, the O-ring 23e of the shaft 23c is interposed between the inner surface of the through hole 24 and the lateral surface of the shaft 23c and also brought into press contact with the inner surface of the through hole 24, thereby blocking communication between the inside and outside of the transfer unit 11 through the through hole 24. That is, the O-ring 23e seals the inside of the transfer unit 11 from the outside thereof. Here, the O-ring 23e is inserted into the O-ring groove formed on the shaft 23c. An O-ring groove may be also formed on the inner surface of the through hole 24, and when the shaft 23c is inserted into the through hole 24, the O-ring 23e of the shaft 23c may be insertion-fitted into the O-ring groove formed on the inner surface of the through hole 24. Alternatively, without forming the O-ring groove on the shaft 23c, the O-ring groove may be formed only on the inner surface of through hole 24 and the O-ring 23e may be insertion-fitted only into the O-ring groove formed on the inner surface of the through hole 24

Since the O-ring 23e surrounds the shaft 23c, a reaction force received by the O-ring 23e from the inner surface of the through hole 24 acts on the shaft 23c in all directions. Thus, the shaft 23c is set to be positioned at the center of the through hole 24 such that the through hole 24 and the shaft 23c are concentric with each other. That is, the position of the adaptor 23 is determined only by inserting the shaft 23c into the through hole 24 and screw-coupling the shaft 23c with the nut 25.

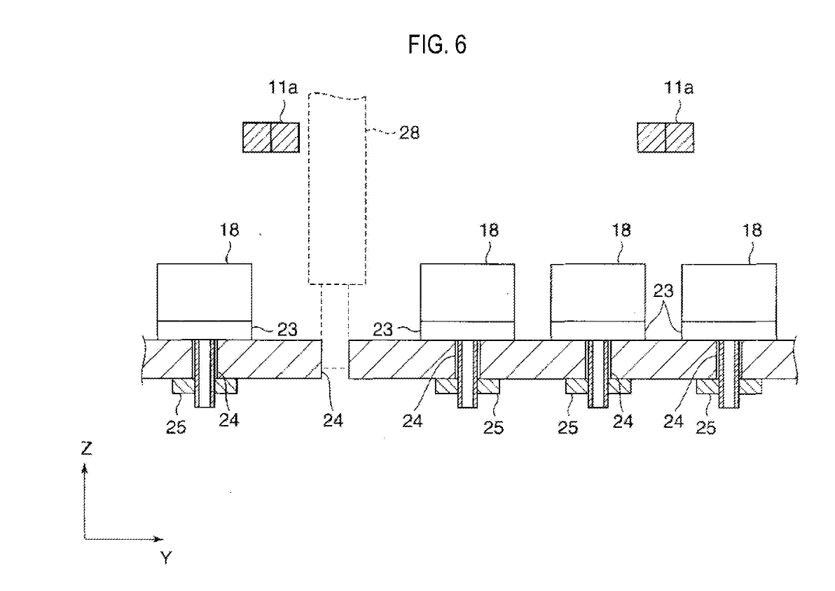

According to the transfer module 12 as the transfer device of the present embodiment, since the O-ring 23e is interposed between the inner surface of each through hole 24 of the transfer unit 11 and the lateral surface of each shaft 23c, it is not necessary to seal the gap between the inner wall surface of the transfer unit 11 and the base portion 23a of each adaptor 23 and to form the seal groove on the inner wall surface of the transfer unit 11. In addition, since the adaptor 23 can be installed on the transfer unit 11 only by forming the through hole 24 into which the shaft 23c is inserted, it is not necessary to form a plurality of screw holes in the inner wall surface of the transfer unit 11 in order to install the adaptor 23. As a result, as shown in FIG. 6, since an interference between a ceiling portion 11a of the transfer unit 11 and a machining tool 28 is not needed, a large degree of freedom in formation position of each through hole 24 and a large degree of freedom in arrangement of the coil 18 attached to each adaptor 23, which is position-determined by each through hole 24, can be secured. Therefore, the plurality of coils 18 can be uniformly arranged in each transfer unit 11, thereby realizing the smooth movement of the slide box 17 disposed between the pair of coil arrays 15.

In the above-described transfer module 12, since the O-ring 23e surrounding the shaft 23c seals the inside of the transfer unit 11 from the outside thereof, the circumferential length of the O-ring can be shortened as compared with the case where the O-ring is disposed in the seal groove formed on the inner wall surface of the transfer unit 11. As a result, the possibility that the O-ring is broken or has a compression defect can be reduced, which improves the sealing capability of the inside of the transfer unit 11 from the outside thereof.

Further, in the above-described transfer module 12, since the shaft 23c is male-threaded and the nut 25 is screw-coupled to the portion of the shaft 23c protruding from the through hole 24 so that the adaptor 23 is tightly fixed to the transfer unit 11, it is not necessary to additionally form screw holes or the like for fixing the adaptor 23 in the transfer unit 11. Thus, the interference between the ceiling portion 11a of the transfer unit 11 and the machining tool 28 does not need to be considered securely.

In transfer modules using the conventional linear motor mechanism, since the coils are arranged in the transfer space that is under a depressurized environment, the heat generated when the electromagnetic force is generated cannot be removed by convection of air. Thus, in order to suppress the heat generation amount of the coils, the coils only generate an electromagnetic force at just several ten percent of the rated power, which lowers electromagnetic driving efficiency of the slide box 17.

In the above-described transfer module 12, a cooling mechanism is installed in the adaptor 23 in order to cool the coil 18. Specifically, a coolant channel 23g is formed inside the base portion 23a of the adaptor 23, a hollow portion 23h is formed to penetrate through the shaft 23c in the axial direction, and a tubular coolant supply path 26 is disposed to pass through the hollow portion 23h and reach the coolant channel 23g. The coolant supply path 26 circularly supplies the coolant channel 23g with a coolant, for example, cold water or cold air, thereby cooling the adaptor 23 and further cooling the coil 18.

Accordingly, since it is not necessary to consider the heat generated when the electromagnetic force is generated by the coils 18, the coils 18 can generate the electromagnetic forces almost at the rated power, and thus, the electromagnetic driving efficiency of the slide box 17 can be improved.

In addition, the adaptor 23 has a power supply line 27, which passes through the hollow portion 23h and the base portion 23a to reach the electric contact 23f from outside the transfer unit 11. Accordingly, a through hole for the power supply line 27 does not need to be additionally formed in the transfer unit 11, thereby more securely removing the need to consider the interference between the ceiling portion 11a of the transfer unit 11 and the machining tool 28.

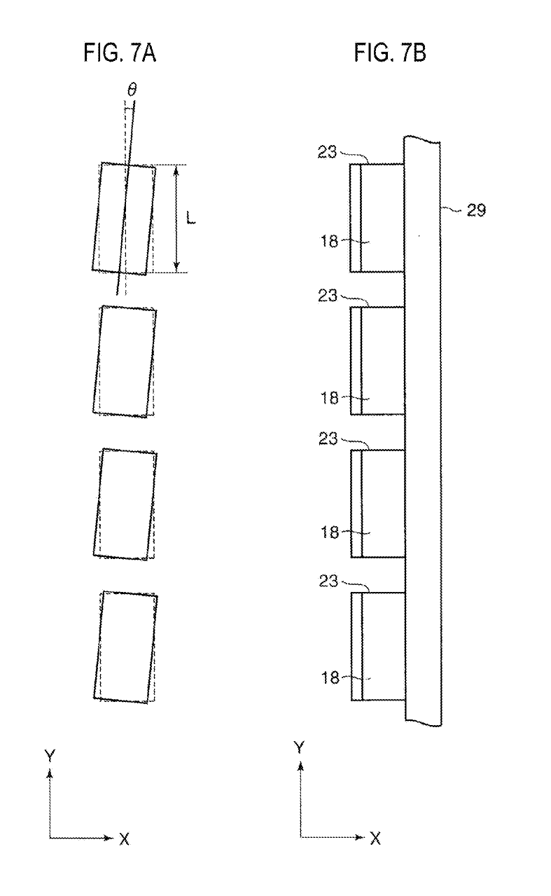

In transfer modules using the conventional linear motor mechanism, since each coil is a part separate from the transfer unit, misalignment easily occurs when each coil 18 is installed on the transfer unit. For example, as shown in FIG. 7A, when each coil is misaligned by an angle θ in the rotational direction with respect to the arrangement direction of the each transfer unit (as shown by broken lines), with regard to each one of the coils, a distance between the coil and the permanent magnet of the transfer base is varied according to portions in the coil, which makes the electromagnetic driving force acting on the permanent magnets and further the transfer base unstable. In addition, since the misalignment amount L×θ (wherein L is a length of the coil in the arrangement direction) in one coil is accumulated by the number of the coils in the coil array and influences on the movement of the transfer base, it is likely that the transfer base cannot move in a desired direction.

However, in the above-described transfer module 12, since each adaptor 23 is position-determined with respect to the transfer unit 11 only by the single shaft 23c, the adaptor 23 can be freely rotated about the shaft 23c, and thus the misalignment in the rotational direction can be resolved by easily rotating the adaptor 23 and further the coil 18 with respect to the arrangement direction of each transfer unit 11. For example, as shown in FIG. 7B, by bringing a straight lateral surface of a jig 29 into contact with the respective adaptors 23 after the adaptors 23 are installed on the transfer unit 11, the misalignment in rotational direction can be resolved by rotating the adaptors 23. As a result, the electromagnetic force acting on the slide box 17 can be stabilized and the slide box 17 can be securely moved in a desired direction.

Hereinabove, while the present disclosure has been described with the embodiments, the present disclosure is not limited to the above-described embodiments.

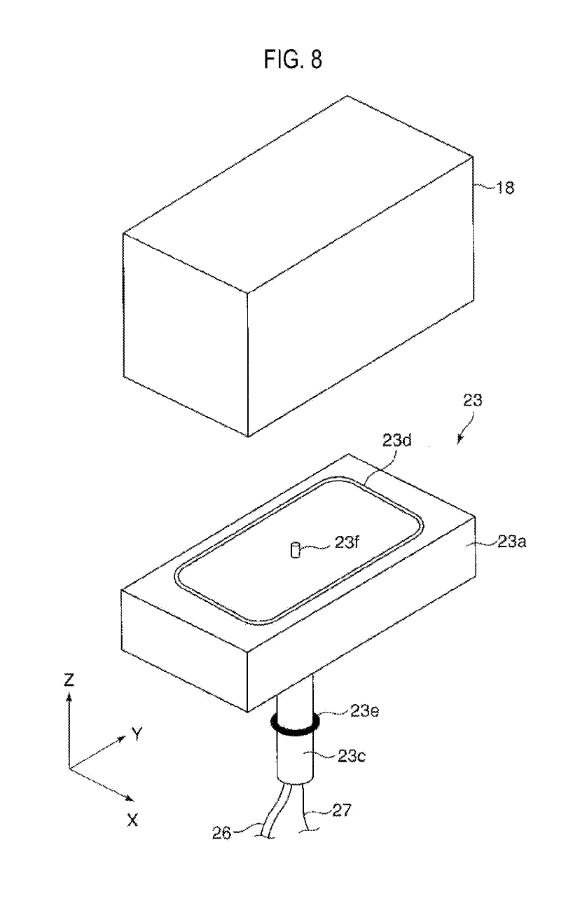

As shown in FIG. 8, the stopper 23b does not need to be necessarily installed on the adaptor 23. In this case, since a degree of freedom in position-determination of the coil 18 with respect to the adaptor 23 is increased, for example, when the coil 18 is misaligned in the rotational direction with respect to the arrangement direction of the transfer units 11, the misalignment in rotational direction may be resolved by rotating the coil 18, instead of rotating the adaptor 23. The misalignment in the rotational direction may also be resolved by rotating the adaptor 23 and also rotating the coil 18 with respect to the adaptor 23.

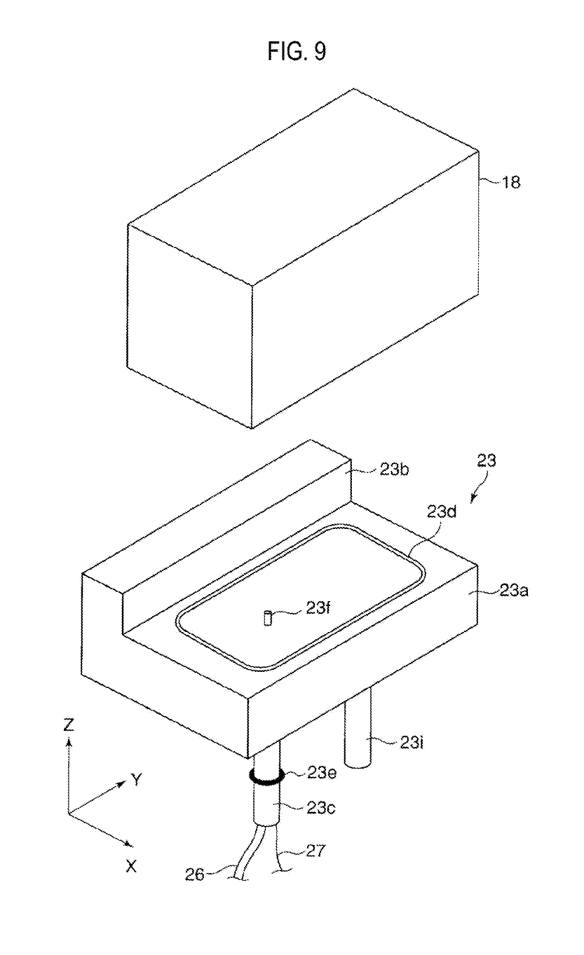

In addition, as shown in FIG. 9, the adaptor 23 may be provided with another shaft 23i in addition to the shaft 23c. However, in this case, it is preferred that the other shaft 23i does not contribute to position-determination of the adaptor 23 in order to secure a degree of freedom in the rotational direction of the adaptor 23 with respect to the arrangement direction of the transfer units 11.

The installation configuration of the coil 18 using the adaptor 23 of the transfer module 12 according to the present embodiment may be applied to not only the case where the transfer module 12 is configured with a plurality of transfer units 11 but also a case where the transfer module 12 is configured with a single transfer unit 11, i.e., a case where the transfer module cannot be elongated. In addition, the installation configuration of the coil 18 using the adaptor 23 of the transfer module 12 according to the present embodiment can be applied when the transfer module 12 has a shape other than the rectangular parallelepiped and the plurality of process modules 13 are radially connected to the transfer module 12.

According to the embodiment of the present disclosure, since a sealing member is interposed between each through hole of the transfer unit and a protrusion of each fitting part, it is not necessary to seal the gap between the inner wall surface of the transfer unit and the fitting part and to form a seal groove on the inner wall surface of the transfer unit. In addition, since the fitting part can be installed on the transfer unit only by forming the through hole 24 into which the protrusion is inserted, it is not necessary to form a plurality of screw holes in the inner wall surface of the transfer unit in order to install the fitting part. As a result, since an interference between a ceiling portion of the transfer unit and a machining tool is not needed, a large degree of freedom in formation position of each through hole and a large degree of freedom in arrangement of the coil attached to each fitting part, which is position-determined by each through hole, can be secured. Therefore, the plurality of coils can be uniformly arranged in each transfer unit, thereby realizing the smooth movement of the transfer base disposed between the pair of coil arrays.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A transfer device configured by connecting a plurality of housing-shaped transfer units in series, the transfer device comprising:
a pair of coil arrays including a plurality of coils arranged in the transfer units along an arrangement direction of the plurality of transfer units;
a transfer base disposed between the pair of coil arrays and configured to move in the transfer unit along the arrangement direction to transfer a substrate; and
a plurality of fitting parts installed in one to one correspondence with the coils, each of the fitting parts being interposed between a corresponding one of the coils and an inner wall surface of one of the transfer units so that each of the coils is installed on a corresponding one of the fitting parts,
wherein an inside of each of the transfer units is depressurized below atmospheric pressure,
wherein the transfer base has a plurality of magnets facing each of the pair of coil arrays,
wherein a plurality of through holes are formed in one to one correspondence with the coils in each of the transfer units, the through holes penetrating from inside of the transfer units to outside of the transfer units,
wherein each of the fitting parts has a bar-shaped protrusion configured to be inserted into a corresponding one of the through holes, and
wherein a sealing member is interposed between the protrusion and the corresponding one of the through holes.

2. The transfer device of claim 1, wherein each of the fitting parts has a coolant channel formed therein and a coolant supply path penetrating through the protrusion in an axial direction to supply a coolant to the coolant channel.

3. The transfer device of claim 1, wherein each of the fitting parts has a power supply line penetrating through the protrusion in an axial direction to reach the corresponding one of the coils installed on the fitting parts.

4. The transfer device of claim 1, wherein the protrusion is male-threaded, and each of the fitting parts is fixed to one of the transfer units by screw-coupling a nut to a portion of the protrusion protruding from the corresponding one of the through holes.

5. The transfer device of claim 1, wherein the transfer base has a transfer arm configured to mount the substrate, the transfer arm being at least rotatable or extendable.
